(19) United States
(12) Patent Application Publication
(10) Pub. No.: US 2026/0197950 A1
(43) Pub. Date: Jul. 9, 2026

(54) STRETCHABLE RIGID-FLEX INTERCONNECTOR AND MANUFACTURING METHOD THEREFOR

(71) Applicants: MFLEX (YAN CHENG) CO., LTD., YANCHENG (CN); AGENCY FOR SCIENCE, TECHNOLOGY AND RESEARCH, SINGAPORE (SG); DSBJ PTE. LTD., SINGAPORE (SG)

(72) Inventors: YEOW MENG TAN, SINGAPORE (SG); ZHISAN HAN, SINGAPORE (SG); QIAN RU CHAN, SINGAPORE (SG)

(73) Assignees: MFLEX (YAN CHENG) CO., LTD., YANCHENG (CN); AGENCY FOR SCIENCE, TECHNOLOGY AND RESEARCH, SINGAPORE (SG); DSBJ PTE. LTD., SINGAPORE (SG)

(21) Appl. No.: 19/363,653

(22) Filed: Oct. 21, 2025

Related U.S. Application Data
(63) Continuation of application No. PCT/CN2025/071386, filed on Jan. 9, 2025.

(51) Int. Cl. H05K 3/46; H05K 1/09; H05K 3/12; H05K 3/28

(52) U.S. Cl. CPC H05K 3/4691; H05K 1/095; H05K 3/1283; H05K 3/28

(57) ABSTRACT

This application discloses a stretchable rigid-flex interconnector and a manufacturing method therefor. The method includes: separately printing silver paste and a liquid metal polymer composite on a first side of a stretchable substrate to form a non-stretchable circuit layer and a stretchable circuit layer; encapsulating the first rigid-flex composite structure using a sealant to form a sealing layer; and attaching a support layer to a second side of the second rigid-flex composite structure, to obtain a target rigid-flex interconnector. According to this application, a rigid-flex interconnector for an electronic interconnection between a rigid circuit system and a flexible circuit system can be truly formed. The entire rigid-flex interconnector has excellent stretchability.

### CROSS-REFERENCE OF RELATED APPLICATION

This application claims priority to Singapore Patent Application No. SG10202400291S, filed on Jan. 31, 2024, which is incorporated herein by reference in its entirety, and claims priority to China Patent Application No. 2024109708014, entitled “STRETCHABLE RIGID-FLEX INTERCONNECTOR AND MANUFACTURING METHOD THEREFOR”, filed on Jul. 19, 2024, with DAS of B4FF, which is incorporated herein by reference in its entirety.

### TECHNICAL FIELD

This application relates to the field of rigid-flex interconnection technologies, and specifically, to a stretchable rigid-flex interconnector and a manufacturing method therefor.

### BACKGROUND

A rigid-flex interconnector is an electronic system that has both a rigid circuit system and a flexible circuit system, and the two circuit systems need to be electrically interconnected. The rigid circuit system usually means a rigid and non-stretchable circuit module, and the flexible circuit system usually means a flexible and stretchable circuit module. With the development of science and technology, rigid-flex interconnectors have been widely used in medical, military, robotics, and other fields. Especially in the field of wearable electronic technologies, an interconnection between a flexible and stretchable circuit module (that is, a flexible circuit system) and a rigid and non-stretchable circuit module (that is, a rigid circuit system) is almost inevitable.

A present, most rigid-flex interconnectors use a manner of designing serpentine circuits within flexible circuit systems to reduce tensile stress of the interconnectors, so as to implement stretchable rigid-flex interconnectors. However, in the foregoing rigid-flex interconnector, only the serpentine circuit in the flexible circuit system can be stretched, and its stretchability is limited; and a substrate of the flexible circuit system can only be bent but cannot be stretched. Therefore, the entire rigid-flex interconnector has poor stretchability, and cannot meet requirements of rigid-flex interconnection electronic products such as wearable electronic apparatuses at the present stage.

### SUMMARY

In view of this, this application provides a stretchable rigid-flex interconnector and a manufacturing method therefor, to solve a problem that only an internal circuit of the existing rigid-flex interconnector is stretchable and a substrate itself is non-stretchable, which leads to poor stretchability.

This application provides a manufacturing method for a stretchable rigid-flex interconnector, including:
providing a stretchable substrate, separately printing silver paste and a liquid metal polymer composite on a first side of the stretchable substrate to form a non-stretchable circuit layer and a stretchable circuit layer, so as to obtain a first rigid-flex composite structure, where the non-stretchable circuit layer and the stretchable circuit layer have an overlapping region at an interface;
providing a sealant, and encapsulating the first rigid-flex composite structure using the sealant to form a sealing layer, so that the stretchable circuit layer is covered by the sealing layer, to obtain a second rigid-flex composite structure; and
providing a support layer, and attaching the support layer to a second side of the second rigid-flex composite structure, to obtain a target rigid-flex interconnector.

Optionally, the liquid metal polymer composite is made of silver powder, liquid metal, and styrene-ethylene-butylene-styrene block copolymer.

Optionally, weight percentages of the silver powder, the liquid metal, and the styrene-ethylene-butylene-styrene block copolymer in the liquid metal polymer composite are 28.2%, 68.3%, and 3.4% respectively.

Optionally, the liquid metal is specifically a gallium-indium alloy, and a weight ratio of gallium to indium in the gallium-indium alloy is 3:1.

Optionally, a length of the overlapping region between the non-stretchable circuit layer and the stretchable circuit layer in a stretching direction of the stretchable circuit layer is greater than or equal to 0.1 mm.

Optionally, the stretchable substrate includes a polymer film layer and a hot melt adhesive layer, where
the polymer film layer has a thickness of 75 μm, and/or the hot melt adhesive layer has a thickness of 25 μm.

Optionally, the polymer film layer includes any one of a silicone film layer, an acrylic polymer film layer, and a polyurethane film layer.

Optionally, separately printing the silver paste and the liquid metal polymer composite on the first side of the stretchable substrate to form the non-stretchable circuit layer and the stretchable circuit layer, so as to obtain the first rigid-flex composite structure includes:
providing the silver paste, and printing the silver paste on a side, provided with the polymer film layer, of the stretchable substrate;
curing, based on first specified curing parameters, the stretchable substrate on which the silver paste is printed, to form the non-stretchable circuit layer;
providing the liquid metal polymer composite, and printing the liquid metal polymer composite on the side, provided with the polymer film layer, of the stretchable substrate; and
drying, based on specified drying parameters, the stretchable substrate on which the liquid metal polymer composite is printed, to form the stretchable circuit layer that is electrically connected to the non-stretchable circuit layer, so as to obtain a first rigid-flex composite structure.

Optionally, the first specified curing parameters include a first curing time and a first curing temperature; and/or the specified drying parameters include a drying time and a drying temperature.

Optionally, the first curing time is 30 minutes, and/or the first curing temperature is 80° C.; and the drying time is 60 minutes, and/or the drying temperature is 60° C.

Optionally, attaching the support layer to the second side of the second rigid-flex composite structure includes:
bonding the support layer to a side, provided with the hot melt adhesive layer, of the second rigid-flex composite structure; and
thermally laminating, based on specified lamination parameters, the second rigid-flex composite structure to which the support layer is bonded.

Optionally, the specified lamination parameters include a lamination temperature, a lamination time, and a lamination pressure, where
the lamination temperature ranges from 100° C. to 120° C.; and/or the lamination time ranges from 10 s to 30 s; and/or the lamination pressure ranges from 4 Bar to 7 Bar.

Optionally, encapsulating the first rigid-flex composite structure using the sealant to form the sealing layer, so that the stretchable circuit layer is covered by the sealing layer, so obtain the second rigid-flex composite structure includes:
printing the sealant to a side, provided with the stretchable circuit layer, of the first rigid-flex composite structure; and
curing, based on second specified curing parameters, the first rigid-flex composite structure on which the sealant is printed to form the sealing layer on the first rigid-flex composite structure, so that the stretchable circuit layer is completely covered by the sealing layer, to obtain the second rigid-flex composite structure.

Optionally, the second specified curing parameters include a second curing time and a second curing temperature, where
the second curing time is 2 hours; and/or the second curing temperature is 80° C.

Optionally, the non-stretchable circuit layer has a thickness ranging from 1 μm to 100 μm; and/or the stretchable circuit layer has a thickness ranging from 1 μm to 300 μm.

Optionally, the sealing layer has a thickness ranging from 0.1 mm to 2 mm.

Optionally, the sealing layer includes any one or a combination of several of a silicone film layer, an acrylic polymer film layer, and a polyurethane film layer.

Optionally, a projection of the support layer onto the stretchable substrate covers a projection of the non-stretchable circuit layer onto the stretchable substrate.

Optionally, after attaching the support layer to the second side of the second rigid-flex composite structure, the method further includes:
mounting an electronic component on the non-stretchable circuit layer in the second rigid-flex composite structure to which the support layer is attached, so that electrical conduction is formed between the electronic component and the non-stretchable circuit layer; and
curing, based on third specified curing parameters, the second rigid-flex composite structure on which the electronic component is mounted.

Optionally, the third specified curing parameters include a third curing time and a third curing temperature, where
the third curing time is 30 minutes; and/or the third curing temperature is 120° C.

In addition, this application further provides a stretchable rigid-flex interconnector, which is manufactured by using the foregoing manufacturing method for a stretchable rigid-flex interconnector.

This application has the beneficial effects that: The silver paste is electrically conductive, and may be configured to be flexible but non-stretchable. Therefore, the non-stretchable circuit layer can be formed by printing the silver paste on the first side of the stretchable substrate, which is convenient for subsequently combining the stretchable substrate and the support layer to form a non-stretchable rigid circuit system. The liquid metal polymer composite not only has characteristics of a liquid metal material, that is, it is flexible and stretchable, but also overcomes disadvantages of the liquid metal material, that is, it can avoid the rapid formation of an oxide layer that would hinder wetting of the substrate, so that the stretchable circuit layer with excellent quality can be conveniently manufactured by printing the liquid metal polymer composite on the first side of the stretchable substrate. In combination with stretchability of the stretchable substrate, a flexible circuit system can be formed, and it is ensured that not only the internal circuit but also the entire flexible circuit system has excellent stretchability. With the encapsulation of the sealant, the sealing layer formed can cover the stretchable circuit layer, which can avoid leakage and outflow of the liquid metal polymer composite, and play a role in sealing and protecting the stretchable circuit layer. The support layer is attached to the second side of the second rigid-flex composite structure, which can play a role in supporting the non-stretchable circuit layer.

According to the stretchable rigid-flex interconnector and the manufacturing method therefor provided by this application, based on the stretchable circuit layer and the non-stretchable circuit layer having the overlapping region at the interface, a rigid-flex interconnector for enabling an electronic interconnection between the rigid circuit system and the flexible circuit system can be truly formed. The entire rigid-flex interconnector not only ensures functionality, but also has excellent stretchability, which can meet requirements of rigid-flex interconnection electronic products such as wearable electronic apparatuses at the present stage.

### BRIEF DESCRIPTION OF THE DRAWINGS

Features and advantages of this application will be more clearly understood with reference to the accompanying drawings, which are schematic and should not be construed as limiting this application in any way. In the accompanying drawings:

FIG. 1 is a flowchart of a manufacturing method for a stretchable rigid-flex interconnector according to Embodiment 1 of this application;

FIG. 2 is a top view of a structure in which a non-stretchable circuit layer is formed on a stretchable substrate according to Embodiment 1 of this application;

FIG. 3 is a top view of a structure of a first rigid-flex composite structure obtained according to Embodiment 1 of this application;

FIG. 4 is a cross-sectional view of a structure of a right half of a first rigid-flex composite structure according to Embodiment 1 of this application;

FIG. 5 is a cross-sectional view of a structure of a right half of a second rigid-flex composite structure according to Embodiment 1 of this application;

FIG. 6 is a top view of a structure of a second rigid-flex composite structure obtained according to Embodiment 1 of this application;

FIG. 7 is a model diagram of changes of liquid metal before and after thermal lamination according to Embodiment 1 of this application;

FIG. 8 is a top view of a structure of a second rigid-flex composite structure with a support layer attached according to Embodiment 1 of this application;

FIG. 9 is a cross-sectional view of a structure of a right half of a second rigid-flex composite structure with a support layer attached according to Embodiment 1 of this application;

FIG. 10 is a cross-sectional view of a structure of a first specific implementation of a support layer according to Embodiment 1 of this application;

FIG. 11 is a cross-sectional view of a structure of a second specific implementation of a support layer according to Embodiment 1 of this application;

FIG. 12 is a top view of a structure of a target rigid-flex interconnector obtained according to Embodiment 1 of this application; and

FIG. 13 is a stretchability test curve of a sample manufactured according to Embodiment 1 of this application.

### REFERENCE NUMERALS

1: stretchable substrate; 2: non-stretchable circuit layer; 3: stretchable circuit layer; 4: sealing layer; 5: silver powder; 6: liquid metal; 7: support layer; 8: electronic component; 11: polymer film layer; 12: hot melt adhesive layer; 71: rigid material layer; 72: flexible material layer; 100: overlapping region.

### DETAILED DESCRIPTION OF PREFERRED EMBODIMENTS

To make objectives, technical solutions, and advantages of embodiments of this application clearer, the following clearly and completely describes the technical solutions in the embodiments of this application with reference to the accompanying drawings in the embodiments of this application. It is clear that the described embodiments are merely some rather than all of embodiments of this application. All other embodiments obtained by a person skilled in the art based on embodiments of this application without creative efforts shall fall within the protection scope of this application.

In the descriptions of this application, it should be understood that orientations or positional relationships indicated by the terms “upper”, “lower”, and the like are orientations or positional relationships as shown in the drawings, and are only for the purpose of facilitating and simplifying the descriptions of this application instead of indicating or implying that apparatuses or elements indicated must have particular orientations, and be constructed and operated in the particular orientations, so that these terms are not construed as limiting this application.

It should be noted that, in this application, relational terms such as “first” and “second” are merely used to distinguish one entity or operation from another entity or operation, and do not necessarily require or imply any actual relationship or order between these entities or operations. Moreover, the terms “include,” “comprise,” or any other variant thereof are intended to cover non-exclusive inclusions, such that a process, method, article, or device including a series of elements includes not only those elements, but also other elements that are not explicitly listed, or may further include elements inherent to such a process, method, article, or device. Without further limitation, an element defined by the phrase “comprising/including a . . . ” does not preclude the existence of other identical elements in a process, method, article, or device including the element.

### Embodiment 1

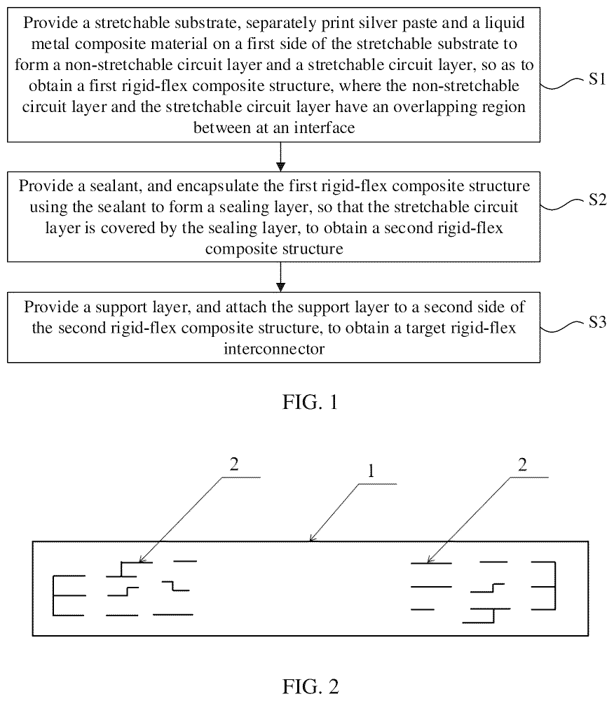

This embodiment provides a manufacturing method for a stretchable rigid-flex interconnector. As shown in FIG. 1, the manufacturing method includes the following steps.
S1: Provide a stretchable substrate, separately print silver paste and a liquid metal polymer composite on a first side of the stretchable substrate to form a non-stretchable circuit layer and a stretchable circuit layer, so as to obtain a first rigid-flex composite structure, where the non-stretchable circuit layer and the stretchable circuit layer have an overlapping region at an interface.
S2: Provide a sealant, and encapsulate the first rigid-flex composite structure using the sealant to form a sealing layer, so that the stretchable circuit layer is covered by the sealing layer, to obtain a second rigid-flex composite structure.
S3: Provide a support layer, and attach the support layer to a second side of the second rigid-flex composite structure, to obtain a target rigid-flex interconnector.

In this embodiment, the silver paste is electrically conductive, and may be configured to be flexible but non-stretchable. Therefore, the non-stretchable circuit layer can be formed by printing the silver paste on the first side of the stretchable substrate, which is convenient for subsequently combining the stretchable substrate and the support layer to form a non-stretchable rigid circuit system. The liquid metal polymer composite not only has the characteristics of a liquid metal material, that is, it is flexible and stretchable, but also overcomes the disadvantages of the liquid metal material, that is, it can avoid the rapid formation of an oxide layer that would hinder wetting of the substrate, so that the stretchable circuit layer with excellent quality can be conveniently manufactured by printing the liquid metal polymer composite on the first side of the stretchable substrate. In combination with stretchability of the stretchable substrate, a flexible circuit system can be formed, and it is ensured that not only the internal circuit but also the entire flexible circuit system has excellent stretchability. Through the encapsulation of the sealant, the sealing layer formed can cover the stretchable circuit layer, which can avoid leakage and outflow of the liquid metal polymer composite, and play a role in sealing and protecting the stretchable circuit layer. The support layer is attached to the second side of the second rigid-flex composite structure, and can play a role in supporting the non-stretchable circuit layer.

According to the manufacturing method for a stretchable rigid-flex interconnector provided in this embodiment, based on the stretchable circuit layer and the non-stretchable circuit layer having the overlapping region at the interface, a rigid-flex interconnector for enabling an electronic interconnection between the rigid circuit system and the flexible circuit system can be truly formed. The entire rigid-flex interconnector not only ensures functionality, but also has excellent stretchability, which can meet requirements of wearable electronic apparatuses at the present stage.

It should be understood that the silver paste, the liquid metal polymer composite, and the sealant are all manufactured on the first side of the stretchable substrate, and the support layer is manufactured on a second side of the stretchable substrate. Therefore, the steps of manufacturing the non-stretchable circuit layer, the stretchable circuit layer, and the sealing layer in foregoing S1 and S2 of this embodiment, and the step of attaching the support layer in S3 of this embodiment are not unique in order, that is, the non-stretchable circuit layer, the stretchable circuit layer, and the sealing layer are first separately manufactured according to steps S1 and S2, and then the support layer is attached according to step S3; alternatively, the support layer is first attached according to step S3, and then the non-stretchable circuit layer, the stretchable circuit layer, and the sealing layer are separately manufactured according to steps S1 and S2. Both can form the rigid-flex interconnector with excellent stretchability in this embodiment. For ease of description, the following embodiment is described by using an example in which the non-stretchable circuit layer, the stretchable circuit layer, and the sealing layer are separately manufactured according to steps S1 and S2, and then the support layer is attached according to step S3. The situation of first attaching the support layer according to step S3, and then separately manufacturing the non-stretchable circuit layer, the stretchable circuit layer, and the sealing layer according to steps S1 and S2, is not repeated herein.

Each step of the manufacturing method for a stretchable rigid-flex interconnector in this embodiment is described in detail below.

In S1, the stretchable substrate provided includes a polymer film layer and a hot melt adhesive layer.

The polymer film layer has a better elongation, and the entire stretchable substrate can have good stretchability by using the polymer film layer, which is convenient for providing excellent stretchability for the flexible circuit system together with the subsequently printed liquid metal polymer composite. By using the hot melt adhesive layer, the support layer can be easily bonded subsequently, to provide a good support for the stretchable circuit layer, so as to form the rigid circuit system with excellent quality.

Preferably, the polymer film layer includes any one of a silicone film layer, an acrylic polymer film layer, and a polyurethane film layer.

The silicone film layer (for example, Dragon Skin silicone produced by Smooth-On, USA) is mainly formed by cross-linking and curing of polydimethylsiloxane (PDMS) polymer, has a low Young's modulus, good flexibility and stretchability, strong corrosion resistance, and high dielectric strength, has good transparency and stability in a wide range of application temperatures, and can be used as a base material for large-area transparent flexible electronic devices or thermally stable devices. In addition, the silicone film layer can be easily combined with electronic materials to fasten the electronic materials on a surface thereof, which is convenient for separately printing silver paste to form the non-stretchable circuit layer.

The acrylic polymer film layer (for example, a 3M VHB adhesive manufactured by 3M) is a film material layer made of acrylic polymer and has excellent film forming property, excellent chemical stability, good mechanical property and good processability. The polyurethane film layer (for example, thermoplastic polyurethanes, TPU) is a film made of a polymer material polyurethane (PU), has a unique block molecular structure, excellent wear resistance, flexibility, tear resistance, and good elasticity, and can adapt to various complex deformations and stretching.

The foregoing polymer film layers can all ensure that the stretchable substrate has good stretchability.

In an alternative embodiment, a TPU5855 film is selected for the stretchable substrate, that is, the polymer film layer therein is a TPU film having a thickness of 75 μm, exhibiting higher elongation, such as typical elongation at fracture of more than 500%, and good recovery ability, such as less than 5% permanent deformation after 100% strain. The hot melt adhesive layer is an FDS5855X1 hot melt adhesive having a thickness of 25 μm.

In S1 of this embodiment, the silver paste has high conductivity, good chemical stability, and is not easily oxidized. Even if a surface of the silver paste is partially oxidized, resulting oxides may still be electrically conductive, which enables the silver paste to ensure smooth transmission of a current in the application of the circuit layer. In combination with a printing process, the circuit wire formed has higher resolution, better conductivity, denser structure and brighter surface, is more resistant to moisture and corrosion of a silk-screened copper wire, and has good adhesion to a base material and is not easy to fall off the stretchable substrate, so that it is possible to print electronic products with more complex structures and larger areas on the stretchable substrate.

In an alternative embodiment, the silver paste may be ASH LS-411 or ASH LS-453 silver paste.

Liquid metal is a good electrical conductor for flexible and stretchable media. However, it is difficult to directly use the liquid metal as conductive ink because the liquid metal may quickly form an oxide layer that hinders wetting of the substrate. In this embodiment, a liquid metal polymer composite (LMPC for short) is used, which not only maintains material characteristics of the liquid metal, that is, it is flexible and stretchable, but also can overcome disadvantages of the liquid metal, and can avoid rapid formation of an oxide layer that hinders the wetting of the substrate.

In S1 of this embodiment, the liquid metal polymer composite is made of silver powder, liquid metal, and styrene-ethylene-butylene-styrene block copolymer.

In the foregoing liquid metal polymer composite, both flaky silver powder and a compatible stretchable polymer (that is, styrene-ethylene-butylene-styrene block copolymer) binder are added, and the liquid metal is used as a dual phase in an Ag/bonder matrix, which can improve processability of the liquid metal.

Preferably, weight percentages of the silver powder, the liquid metal, and the styrene-ethylene-butylene-styrene block copolymer in the liquid metal polymer composite, are 28.2%, 68.3%, and 3.4% respectively.

The stretchable circuit layer formed by the liquid metal polymer composite (LMPC) with the foregoing weight percentages has excellent stretchability and can be used in regions requiring high tensile strain in rigid-flex interconnectors. The stretchable circuit layer can be used not only as a conductive wire in a flexible circuit system, but also as a strain buffer of a rigid-flex interconnector. In addition, when the separated flaky Ag powder is stretched apart, the liquid metal in the LMPC acts as a “healing” medium to bridge the separation, so as to maintain electrical continuity.

Specifically, the liquid metal is specifically a gallium-indium alloy, and a weight ratio of gallium to indium in the gallium-indium alloy is 3:1.

When the weight ratio of gallium to indium in the gallium-indium alloy is 3:1, the alloy has the advantages of low melting point, good thermal stability, high electrical conductivity, good plasticity and ductility, and the like, and can be more convenient for the manufacturing of the liquid metal polymer composite, and ensuring functionality of the stretchable circuit layer formed.

Preferably, in S1 of this embodiment, separately printing the silver paste and the liquid metal polymer composite on the first side of the stretchable substrate to form the non-stretchable circuit layer and the stretchable circuit layer, so as to obtaining the first rigid-flex composite structure includes the following steps.
S11: Provide the silver paste, printing the silver paste on a side, provided with the polymer film layer, of the stretchable substrate.
S12: Cure, based on first specified curing parameters, the stretchable substrate on which the silver paste is printed, to form the non-stretchable circuit layer.
S13: Provide the liquid metal polymer composite, print the liquid metal polymer composite on a side, provided with the polymer film layer, of the stretchable substrate using a dispense printing or stencil printing method.
S14: Dry, based on specified drying parameters, the stretchable substrate on which the liquid metal polymer composite is printed, to form the stretchable circuit layer that is electrically connected to the non-stretchable circuit layer, so as to obtain the first rigid-flex composite structure.

In S11, the silver paste may be printed using a dispense printing or screen printing method. Dispense printing (Dispensing Printing) is a process of continuously dispensing materials on specified positions via a dispenser to implement continuous printing of electronic circuits. Screen printing (Screen Printing, also referred to as silk-screen printing) is a process of using a screen as a plate base to make a screen plate with pictures and text by using a photosensitive plate making method, and then printing electronic circuits using the screen plate.

In S13, the liquid metal polymer composite may be printed using the dispense printing or stencil printing method. Stencil printing (Stencil Printing) is a process of engraving pictures and text on a sheet such as a wood sheet, a cardboard, a metal sheet, or a plastic sheet, hollowing out to form a hollow plate, and attaching ink to a printing stock via through holes using a brushing or spraying method to implement electronic circuits printing.

When the silver paste is printed to manufacture the non-stretchable circuit layer in S11, a position and a layout of the non-stretchable circuit layer can be efficiently and accurately controlled using the dispense printing or screen printing method. After printing, the stretchable substrate printed with the silver paste is cured based on the first specified curing parameters in S12, which can ensure that the manufactured non-stretchable circuit layer meets design requirements, and improve manufacturing precision and manufacturing efficiency of the non-stretchable circuit layer. When the liquid metal polymer composite is printed in S13, the dispense printing or stencil printing method is used, which can adapt to characteristics of the liquid metal polymer composite, and efficiently and accurately control the position and layout of the stretchable circuit layer. After printing, the stretchable substrate printed with the liquid metal polymer composite is dried based on the specified drying parameters in S14, which can also ensure that the manufactured non-stretchable circuit layer meets the design requirements, and improve the manufacturing precision and the manufacturing efficiency of the stretchable circuit layer.

Specifically, the first specified curing parameters include a first curing time and a first curing temperature.

Specifically, the specified drying parameters include a drying time and a drying temperature.

Based on the first specified curing parameters, the material characteristics of the silver paste can be better adapted, and then a molding effect of the non-stretchable circuit layer can be controlled. Similarly, based on the foregoing specified drying parameters, the material characteristics of the liquid metal polymer composite can be better adapted, and then the molding effect of the stretchable circuit layer can be controlled.

In an alternative embodiment, for the silver paste, the first curing time is 30 minutes; and/or the first curing temperature is 80° C.

In an alternative embodiment, for the liquid metal polymer composite, the drying time is 60 minutes; and/or the drying temperature is 60° C.

In an alternative embodiment, the non-stretchable circuit layer has a thickness ranging from 1 μm to 100 μm; and/or the stretchable circuit layer has a thickness ranging from 1 μm to 300 μm.

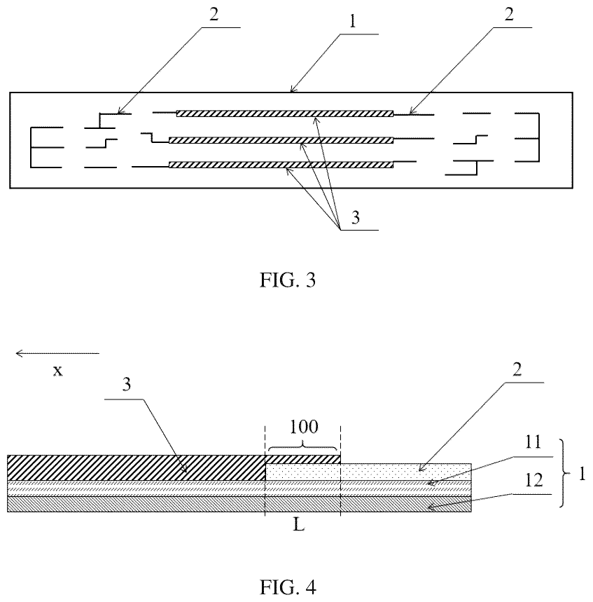

It should be understood that in this embodiment, the steps of manufacturing the non-stretchable circuit layer in S11 and S12 and the steps of manufacturing the stretchable circuit layer in S13 and S14 are not unique in order. The non-stretchable circuit layer may be first manufactured, or the stretchable circuit layer may be first manufactured. In an alternative embodiment, an order of first manufacturing the non-stretchable circuit layer and then manufacturing the stretchable circuit layer is used. A top view of a structure in which the non-stretchable circuit layer is formed on the stretchable substrate is shown in FIG. 2. Based on FIG. 2, the stretchable circuit layer is formed on the stretchable substrate, and a top view of a structure of the obtained first rigid-flex composite structure is shown in FIG. 3. In FIG. 2 and FIGS. 3, 1 is the stretchable substrate, 2 is the non-stretchable circuit layer, and 3 is the stretchable circuit layer. A cross-sectional view of a right half part of the first rigid-flex composite structure in FIG. 3 is shown in FIG. 4. In FIGS. 4, 11 is the polymer film layer in the stretchable substrate 1, and 12 is the hot melt adhesive layer in the stretchable substrate 1. A cross-sectional view of a left half part is symmetrical to the cross-sectional view shown in FIG. 4, and is not shown herein.

In FIG. 3, non-stretchable circuit layers 2 are formed at two ends of the stretchable substrate 1, a stretchable circuit layer 3 is formed between the non-stretchable circuit layers 2 at the two ends, and the stretchable circuit layer 3 is electrically connected to the non-stretchable circuit layers 2 at the two ends. In an actual process, a non-stretchable circuit layer 2 may alternatively be formed at one end of the stretchable substrate 1, and a stretchable circuit layer 3 is electrically connected to the non-stretchable circuit layer. Locations, quantities, and layouts of the non-stretchable circuit layer 2 and the stretchable circuit layer 3 depend on specific product designs, and electrical conduction needs to be ensured between the non-stretchable circuit layer 2 and the stretchable circuit layer 3.

Preferably, in S1, a length of the overlapping region between the non-stretchable circuit layer and the stretchable circuit layer in a stretching direction of the stretchable circuit layer is greater than or equal to 0.1 mm.

In FIG. 4, the first side of the stretchable substrate 1 is a region where an upper surface of the stretchable substrate 1 is located, and the second side is a region where a lower surface of the stretchable substrate 1 is located. The stretching direction of the stretchable circuit layer 3 is the x direction in FIG. 4, so that the non-stretchable circuit layer 2 and the stretchable circuit layer 3 have an overlapping region at an interface, that is, 100 in FIG. 4, and a length L of the overlapping region 100 in the x direction is more than or equal to 0.1 mm.

By limiting the length of the overlapping region, electronic interconnection at an interconnection interface between the flexible circuit system and the rigid circuit system can be better ensured, thereby effectively ensuring functionality of the rigid-flex interconnector. In addition, it is further convenient for the sealant to better fill edges of the stretchable circuit layer subsequently, better encapsulate or seal the stretchable circuit layer, and ensure that the sealing layer formed plays a better sealing role.

In S2 of this embodiment, the liquid metal polymer composite may leak or flow out from the matrix during the stretching of the stretchable circuit layer due to flowability of the liquid metal polymer composite. By providing the sealant and encapsulating with the sealant, this situation can be controlled, and printed conductive LMPC traces (namely, the stretchable circuit layer) can be encapsulated or sealed.

The provided sealant includes any one or several of silicone, acrylic polymer, and polyurethane.

The foregoing sealant can not only encapsulate or seal the stretchable circuit layer, but also ensure that the sealant further has stretchability, to be conveniently stretched together with the stretchable circuit layer, so as to implement the rigid-flex interconnector with excellent stretchability.

Based on the foregoing sealant, the sealing layer formed includes any one or a combination of several of a silicone film layer, an acrylic polymer film layer, and a polyurethane film layer.

In an alternative embodiment, the sealant is ecoflex-010 silicone, which is more convenient to be compatible with a stencil printing process.

Preferably, in S2 of this embodiment, encapsulating the first rigid-flex composite structure using the sealant to form the sealing layer, so that the stretchable circuit layer is covered by the sealing layer, so as to obtain the second rigid-flex composite structure includes the following steps.
S21: Print the sealant to a side, provided with the stretchable circuit layer, of the first rigid-flex composite structure.
S22: Cure, based on second specified curing parameters, the first rigid-flex composite structure on which the sealant is printed to form the sealing layer on the first rigid-flex composite structure, so that the stretchable circuit layer is completely covered by the sealing layer, to obtain the second rigid-flex composite structure.

In S21, the sealant is specifically printed on the side, provided with the stretchable circuit layer, of the first rigid-flex composite structure using the stencil printing method, so that printing of the sealant of different shapes and sizes can be easily implemented, stretchable circuit layers of different shapes and sizes can be adapted, and the sealing layer formed subsequently can completely cover the stretchable circuit layer, to have an excellent sealing effect. After the sealant is printed, curing is performed based on the second specified curing parameters in S22, so that the sealing layer can be efficiently formed, thereby further ensuring that the sealing layer has the excellent sealing effect.

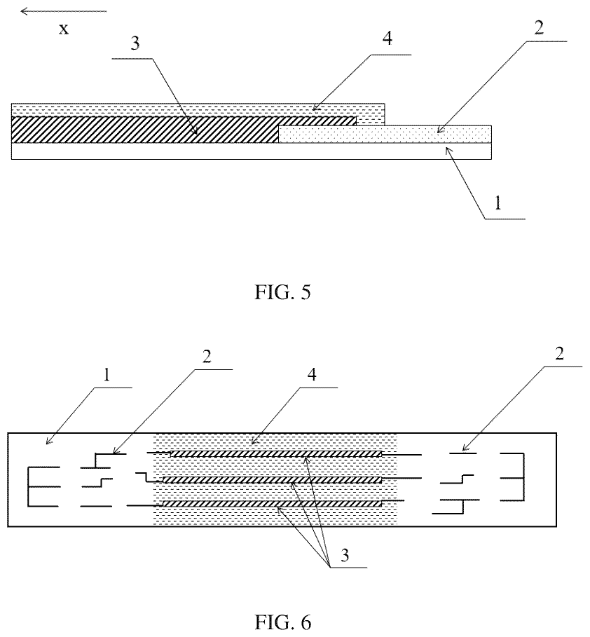

Because the non-stretchable circuit layer and the stretchable circuit layer have the overlapping region at the interface, to ensure that the stretchable circuit layer is completely covered by the sealing layer, edges of the sealing layer may further extend onto the non-stretchable circuit layer. As shown in a cross-sectional view of a right half of the second rigid-flex composite structure in FIG. 5, the sealing layer 4 covers the stretchable circuit layer 3, and the edges of the sealing layer 4 extends onto the non-stretchable circuit layer 2.

A top view of a structure of a second rigid-flex composite structure obtained according to this embodiment is shown in FIG. 6.

Specifically, the second specified curing parameters include a second curing time and a second curing temperature.

Similar to the first specified curing parameters, material characteristics of the sealant can be better adapted based on the foregoing second specified curing parameters, and then a molding effect of the sealing layer can be controlled.

In an alternative embodiment, the second curing time is 2 hours; and/or the second curing temperature is 80° C.

In an alternative embodiment, the sealing layer has a thickness ranging from 0.1 mm to 2 mm.

In an alternative embodiment, specifically, the sealing layer has a thickness of 0.25 mm.

Preferably, in S3 of this embodiment, attaching the support layer to the second side of the stretchable substrate can play a role in supporting the non-stretchable circuit layer on the first side of the stretchable substrate, which ensures that when the stretchable circuit layer is stretched, the non-stretchable circuit layer can be better fastened to the stretchable substrate, and then effectively ensures functionality of the non-stretchable circuit layer, truly implementing an electronic interconnection between the rigid circuit system and the flexible circuit system.

In S3 of this embodiment, attaching the support layer to the second side of the second rigid-flex composite structure includes the following steps.
S31: Bond the support layer to a side, provided with the hot melt adhesive layer, of the second rigid-flex composite structure.
S32: Thermally laminate, based on specified lamination parameters, the second rigid-flex composite structure to which the support layer is bonded.

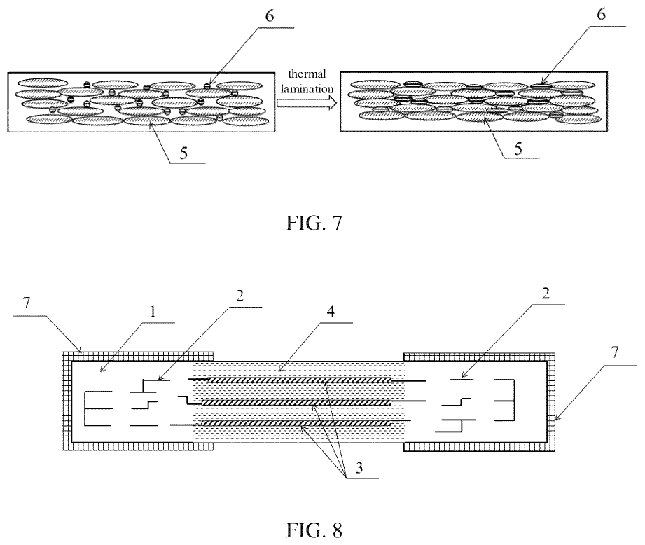

Based on the hot melt adhesive layer in the stretchable substrate, the support layer can be easily bonded to the second side of the stretchable substrate using a thermal lamination method, which ensures that the support layer can play a role in supporting the stretchable circuit layer. In addition, under a thermal lamination pressure, the liquid metal in the stretchable circuit layer may be “squeezed” and fill gaps between the silver powder in the liquid metal polymer composite, as shown in FIG. 7, which may result in better conductivity and further compaction of the liquid metal polymer composite, and forms the stretchable circuit layer with better quality, thereby improving quality of the finally formed target rigid-flex interconnector.

In FIGS. 7, 5 is the silver powder in the liquid metal polymer composite, and 6 is the liquid metal in the liquid metal polymer composite.

Specifically, the specified lamination parameters include a lamination temperature, a lamination time, and a lamination pressure.

Based on the foregoing specified lamination parameters, it can ensure that the support layer that meets requirements is formed, and functionality of the support layer is ensured.

In an alternative embodiment, the lamination temperature ranges from 100° C. to 120° C.; and/or the lamination time ranges from 10 s to 30 s; and/or the lamination pressure ranges from 4 Bar to 7 Bar.

The foregoing parameters can ensure efficient bonding of the support layer, and can also activate the liquid metal filler in the stretchable circuit layer to improve conductivity of the stretchable circuit layer.

Preferably, a projection of the support layer onto the stretchable substrate covers a projection of the non-stretchable circuit layer onto the stretchable substrate.

The projection of the support layer onto the stretchable substrate covers the projection of the non-stretchable circuit layer onto the stretchable substrate, so that the support layer provides better support for the non-stretchable circuit layer, and prevents the rigid circuit system from being stretched along with the flexible circuit system, causing the electronic component in the rigid circuit system to be damaged, thereby ensuring functionality of the final target rigid-flex interconnector.

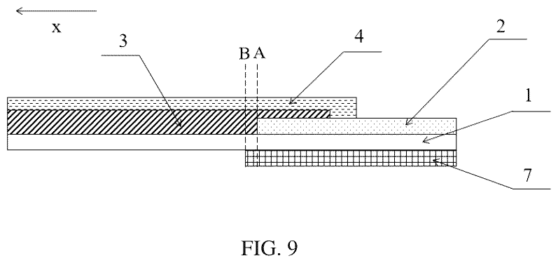

A top view of a structure of the second rigid-flex composite structure to which the support layer is attached provided in this embodiment is shown in FIG. 8, and a cross-sectional view of a corresponding right half part thereof is shown in FIG. 9. In FIG. 8 and FIGS. 9, 7 is the support layer.

In FIG. 9, when the projection of the support layer 7 onto the stretchable substrate 1 covers the projection of the non-stretchable circuit layer 2 onto the stretchable substrate 1, it means that an edge line (line B in FIG. 9), close to the stretchable circuit layer 3, of the support layer 7 is flush with a boundary line (line A in FIG. 9) between the non-stretchable circuit layer 2 and the stretchable circuit layer 3, or the edge line (line B in FIG. 9), close to the stretchable circuit layer 3, of the support layer 7 exceeds the boundary line (line A in FIG. 9) between the non-stretchable circuit layer 2 and the stretchable circuit layer 3. That is, the edge line (line B) of the support layer 7 close to the stretchable circuit layer 3 is closer to the stretchable circuit layer 3 than the boundary line (line A) between the non-stretchable circuit layer 2 and the stretchable circuit layer 3.

The support layer in this embodiment may be a rigid material layer (as shown in FIG. 9), that is, a material layer having a relatively large elastic modulus, including any one of a steel layer (made of steel), a reinforcing layer (made of an organic glass fiber reinforced material that includes glass fiber and epoxy resin), an FR-4 base layer (made of glass fiber reinforced epoxy), a polycarbonate layer (made of PC, where PC is polycarbonate, which is a kind of thermoplastic), a polyethylene terephthalate layer (made of PET, where PET is polyethylene terephthalate, which is a kind of thermoplastic polyester), and a polyimide layer (made of PI, where PI is polyimide).

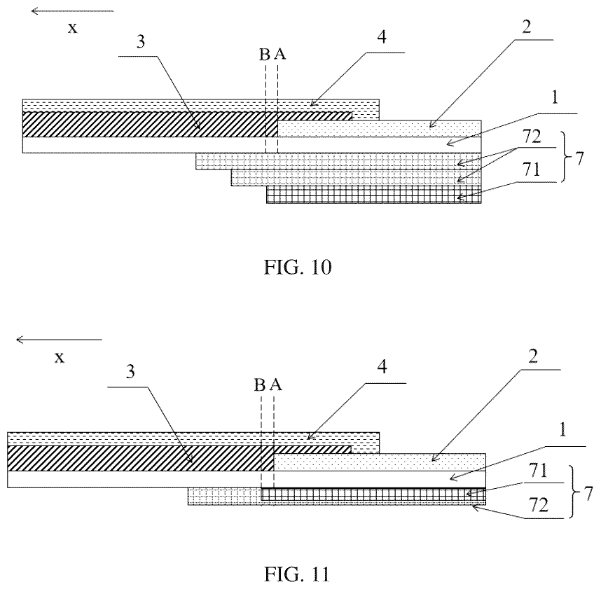

The support layer in this embodiment may alternatively be a support layer with gradient stiffness formed by the combination of at least one flexible material layer and a rigid material layer. The flexible material layer is stacked on the second side of the stretchable substrate in a specified order. The rigid material layer may be stacked on an outer side of all the flexible material layers (as shown in FIG. 10, there are two flexible material layers in FIG. 10) and may be embedded in one of the flexible material layers (as shown in FIG. 11, there is one flexible material layer in FIG. 11). In FIG. 10 and FIG. 11, the rigid material layer is denoted by 71, and the flexible material layer is denoted by 72. In this case, the projection of the support layer onto the stretchable substrate covers the projection of the non-stretchable circuit layer onto the stretchable substrate, which specifically means that a projection of the rigid material layer onto the stretchable substrate covers the projection of the non-stretchable circuit layer onto the stretchable substrate.

The flexible material layer is a material layer having a relatively small elastic modulus, including any one of a silicone layer, an acrylic polymer layer, and a polyurethane layer.

In an alternative embodiment, the support layer is specifically a 0.125 mm rigid PET film.

Preferably, in S3 of this embodiment, after attaching the support layer to the second side of the second rigid-flex composite structure, the method further includes following steps.
S33: Mount an electronic component on the non-stretchable circuit layer in the second rigid-flex composite structure to which the support layer is attached, so that electrical conduction is formed between the electronic component and the non-stretchable circuit layer.
S34: Cure, based on third specified curing parameters, the second rigid-flex composite structure on which the electronic component is mounted.

By executing the foregoing steps, the electronic component may be mounted on the non-stretchable circuit layer, to form the final rigid circuit system that meets design requirements, so as to ensure that the target rigid-flex interconnector that meets the design requirements is manufactured.

In an alternative embodiment, the electronic component (such as a resistor or a capacitor) may be mounted using a conductive adhesive. To improve strength, an SMT adhesive (a patch adhesive or a surface mount adhesive) may alternatively be used, and mounting is performed according to a surface mount technology (that is, SMT). SMT is a conventional mount technology, and specific details are not repeated herein.

Specifically, the third specified curing parameters include a third curing time and a third curing temperature.

Similar to the first specified curing parameters and the second specified curing parameters, based on the foregoing third specified curing parameters, a mounting effect of the electronic component can be better controlled, to ensure that the design requirements are met.

In an alternative embodiment, the third curing time is 30 minutes; and/or the third curing temperature is 120° C.

In an actual manufacturing process, if there is a circuit system that needs to be protected or isolated in the non-stretchable circuit in the product design, after the silver paste is printed on the first side of the stretchable substrate, it further needs to coat the silver paste with a dielectric ink layer, to play a role in insulation and isolation protection.

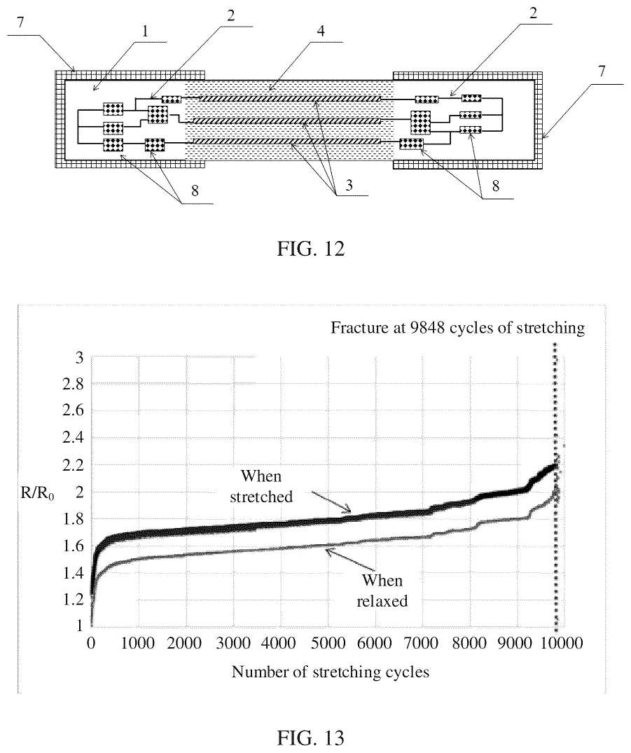

A top view of a structure of the target rigid-flex interconnector obtained according to this embodiment is show in FIG. 12. In FIGS. 12, 8 is the electronic component.

A sample is manufactured using the manufacturing method in this embodiment, with a rigid PET film that is used as the support layer and laminated on a bottom side of the stretchable substrate. Stretching tests are performed at different strain rates for the manufactured sample. For ease of testing, no electronic component is mounted on the sample and only one stretchable circuit layer having only a single stretchable conductive trace is interconnected to a pad in the non-stretchable circuit layer. Stretchability test curves obtained by the stretching test are shown in FIG. 13, where the stretching test is performed at 100% strain and a stretching rate of 3 mm/sec. In FIG. 13, a resistance ratio of the sample manufactured by the manufacturing method in this embodiment after about 10,000 cycles of stretching (that is R/R₀, a ratio of a resistance of the stretchable conductive trace after cyclic stretching to an initial resistance before stretching) is stable, and is approximately 2.20 at the 9823 cycles of stretching (where R₀ ranges from 1 Ω to 2 Ω, which is suitable for most electronic applications), reflecting relatively excellent stretchability and stability.

### Embodiment 2

This embodiment provides a stretchable rigid-flex interconnector, which is manufactured using the manufacturing method for a stretchable rigid-flex interconnector according to Embodiment 1.

The stretchable rigid-flex interconnector manufactured in this embodiment not only ensures functionality, but also has excellent stretchability, which can meet requirements of wearable electronic apparatuses at the present stage.

The manufacturing method for a stretchable rigid-flex interconnector in this embodiment has the same steps as the method described in Embodiment 1. Therefore, for details not provided in this embodiment, reference is made to specific descriptions in Embodiment 1 and FIG. 1 to FIG. 13, and details are not repeated in this embodiment.

Although embodiments of this application have been described with reference to the accompanying drawings, various modifications and variations may be made by those skilled in the art without departing from the spirit and scope of this application, and such modifications and variations fall within the scope defined by the appended claims.

1. A manufacturing method for a stretchable rigid-flex interconnector, comprising:
providing a stretchable substrate, separately printing silver paste and a liquid metal polymer composite on a first side of the stretchable substrate to form a non-stretchable circuit layer and a stretchable circuit layer, so as to obtain a first rigid-flex composite structure, wherein the non-stretchable circuit layer and the stretchable circuit layer have an overlapping region at an interface;
providing a sealant, and encapsulating the first rigid-flex composite structure using the sealant to form a sealing layer, so that the stretchable circuit layer is covered by the sealing layer, to obtain a second rigid-flex composite structure; and
providing a support layer, and attaching the support layer to a second side of the second rigid-flex composite structure, to obtain a target rigid-flex interconnector.

2. The manufacturing method for a stretchable rigid-flex interconnector according to claim 1, wherein the liquid metal polymer composite is made of silver powder, liquid metal, and styrene-ethylene-butylene-styrene block copolymer.

3. The manufacturing method for a stretchable rigid-flex interconnector according to claim 2, wherein weight percentages of the silver powder, the liquid metal, and the styrene-ethylene-butylene-styrene block copolymer in the liquid metal polymer composite are 28.2%, 68.3%, and 3.4% respectively.

4. The manufacturing method for a stretchable rigid-flex interconnector according to claim 2, wherein the liquid metal is specifically a gallium-indium alloy, and a weight ratio of gallium to indium in the gallium-indium alloy is 3:1.

5. The manufacturing method for a stretchable rigid-flex interconnector according to claim 1, wherein a length of the overlapping region between the non-stretchable circuit layer and the stretchable circuit layer in a stretching direction of the stretchable circuit layer is greater than or equal to 0.1 mm.

6. The manufacturing method for a stretchable rigid-flex interconnector according to claim 1, wherein the stretchable substrate comprises a polymer film layer and a hot melt adhesive layer, wherein
the polymer film layer has a thickness of 75 μm, and/or the hot melt adhesive layer has a thickness of 25 μm.

7. The manufacturing method for a stretchable rigid-flex interconnector according to claim 6, wherein the polymer film layer comprises any one of a silicone film layer, an acrylic polymer film layer, and a polyurethane film layer.

8. The manufacturing method for a stretchable rigid-flex interconnector according to claim 6, separately printing the silver paste and a liquid metal polymer composite on the first side of the stretchable substrate to form the non-stretchable circuit layer and the stretchable circuit layer, so as to obtain the first rigid-flex composite structure comprises:
providing the silver paste, and printing the silver paste on a side, provided with the polymer film layer, of the stretchable substrate;
curing, based on first specified curing parameters, the stretchable substrate on which the silver paste is printed, to form the non-stretchable circuit layer;
providing the liquid metal polymer composite, and printing the liquid metal polymer composite on the side, provided with the polymer film layer, of the stretchable substrate; and
drying, based on specified drying parameters, the stretchable substrate on which the liquid metal polymer composite is printed, to form the stretchable circuit layer that is electrically connected to the non-stretchable circuit layer, so as to obtain a first rigid-flex composite structure.

9. The manufacturing method for a stretchable rigid-flex interconnector according to claim 8, wherein the first specified curing parameters comprise a first curing time and a first curing temperature; and/or the specified drying parameters comprise a drying time and a drying temperature.

10. The manufacturing method for a stretchable rigid-flex interconnector according to claim 9, wherein the first curing time is 30 minutes, and/or the first curing temperature is 80° C.; and the drying time is 60 minutes, and/or the drying temperature is 60° C.

11. The manufacturing method for a stretchable rigid-flex interconnector according to claim 6, wherein attaching the support layer to the second side of the second rigid-flex composite structure comprises:
bonding the support layer to a side, provided with the hot melt adhesive layer, of the second rigid-flex composite structure; and
thermally laminating, based on specified lamination parameters, the second rigid-flex composite structure to which the support layer is bonded.

12. The manufacturing method for a stretchable rigid-flex interconnector according to claim 11, wherein the specified lamination parameters comprise a lamination temperature, a lamination time, and a lamination pressure, wherein
the lamination temperature ranges from 100° C. to 120° C.; and/or the lamination time ranges from 10 s to 30 s; and/or the lamination pressure ranges from 4 Bar to 7 Bar.

13. The manufacturing method for a stretchable rigid-flex interconnector according to claim 1, wherein encapsulating the first rigid-flex composite structure using the sealant to form the sealing layer, so that the stretchable circuit layer is covered by the sealing layer, to obtain the second rigid-flex composite structure comprises:
printing the sealant to a side, provided with the stretchable circuit layer, of the first rigid-flex composite structure; and
curing, based on second specified curing parameters, the first rigid-flex composite structure on which the sealant is printed to form the sealing layer on the first rigid-flex composite structure, so that the stretchable circuit layer is completely covered by the sealing layer, to obtain the second rigid-flex composite structure.

14. The manufacturing method for a stretchable rigid-flex interconnector according to claim 13, wherein the second specified curing parameters comprise a second curing time and a second curing temperature, wherein
the second curing time is 2 hours; and/or the second curing temperature is 80° C.

15. The manufacturing method for a stretchable rigid-flex interconnector according to claim 1, wherein the non-stretchable circuit layer has a thickness ranging from 1 μm to 100 μm; and/or the stretchable circuit layer has a thickness ranging from 1 μm to 300 μm.

16. The manufacturing method for a stretchable rigid-flex interconnector according to claim 1, wherein the sealing layer has a thickness ranging from 0.1 mm to 2 mm.

17. The manufacturing method for a stretchable rigid-flex interconnector according to claim 1, wherein the sealing layer comprises any one or a combination of several of a silicone film layer, an acrylic polymer film layer, and a polyurethane film layer.

18. The manufacturing method for a stretchable rigid-flex interconnector according to claims 1, wherein a projection of the support layer onto the stretchable substrate covers a projection of the non-stretchable circuit layer onto the stretchable substrate.

19. The manufacturing method for a stretchable rigid-flex interconnector according to claims 1, wherein after attaching the support layer to the second side of the second rigid-flex composite structure, the method further comprises:
mounting an electronic component on the non-stretchable circuit layer in the second rigid-flex composite structure to which the support layer is attached, so that electrical conduction is formed between the electronic component and the non-stretchable circuit layer; and
curing, based on third specified curing parameters, the second rigid-flex composite structure on which the electronic component is mounted.

20. The manufacturing method for a stretchable rigid-flex interconnector according to claim 19, wherein the third specified curing parameters comprise a third curing time and a third curing temperature, wherein
the third curing time is 30 minutes; and/or the third curing temperature is 120° C.
